(19) United States
(12) Patent Application Publication
(10) Pub. No.: US 2021/0291765 A1
(43) Pub. Date: Sep. 23, 2021

(54) METHOD FOR CONFIGURING A VEHICLE ELECTRICAL SYSTEM

(71) Applicants: Robert Bosch GmbH, Stuttgart (DE); AUDI AG, Ingolstadt (DE)

(72) Inventors: Nils Draese, Stuttgart (DE); Matthias Zabka, Suessen (DE); Georg Schill, Pforzheim (DE); Werner Schiemann, Fellbach (DE); Sebastian Kaspar, Ingolstadt (DE); Daniel Rabl, Dietfurt (DE)

(21) Appl. No.: 17/201,535

(22) Filed: Mar. 15, 2021

(30) Foreign Application Priority Data
Mar. 19, 2020 (DE) 102020107695.9

(51) Int. Cl. B60R 16/03

(52) U.S. Cl. CPC B60R 16/03

(57) ABSTRACT

A method for configuring a vehicle electrical system of a motor vehicle, at least one consumer being provided in the vehicle electrical system. Within the scope of the configuration of the vehicle electrical system, at least one of the at least one consumer is assigned an electrical module, which in turn is selected from a group of modules. A first consumer criterion, which refers to a supply requirement of the at least one consumer, and a second consumer criterion, which refers to a degree of feedback of the at least one consumer, are taken into consideration in the selection of the electrical module.

### CROSS REFERENCE

The present application claims the benefit under 35 U.S.C. § 119 of German Patent Application No. DE 102020107695.9 filed on Mar. 19, 2020, which is expressly incorporated herein by reference in its entirety.

### FIELD

The present invention relates to a method for configuring a vehicle electrical system and to such a vehicle electrical system.

### BACKGROUND INFORMATION

A vehicle electrical system in automotive applications is to be understood as the totality of all electrical components in a motor vehicle. It therefore comprises both electrical consumers as well as sources of supply such as batteries, for example. One distinguishes in this connection between the energy vehicle electrical system and the communication vehicle electrical system, the present invention being primarily concerned with the energy vehicle electrical system, which is responsible for supplying the components of the motor vehicle with energy.

In modern motor vehicles, the energy flows within an energy vehicle electrical system are often controlled via an energy management system. Usually, a microcontroller is provided for controlling the vehicle electrical system, which also performs monitoring functions in addition to control functions.

In a motor vehicle, it is necessary to ensure that electrical energy is available in such a way that the motor vehicle may be started at any time and that a sufficient supply of current exists during operation. Even in a parked state, electrical consumers should still be operable for a suitable period of time without impairing a subsequent start.

The consumers provided in the vehicle electrical system may be directly connected to the latter or may be coupled to it via components, which are also referred to below as electrical modules.

At present, new components are introduced into energy vehicle electrical systems, which require the integrity of the energy supply at a defined quality and availability, i.e., with ASIL targets (ASIL: Automotive Safety Integrity Level). With regard to the quality, it is necessary to ensure that the supply voltage is guaranteed in a defined target range. Negative feedback effects due to faults and malfunctions must be isolated.

With regard to the availability, this means that there must be an extremely low probability that safety-critical components are disconnected from a stable electrical energy supply. At the same time it is necessary to ensure with very high reliability that faults in the vehicle electrical system are avoided or sources of faults are isolated in order to limit negative feedback effects on the source and subsequently on the safety-critical consumers.

Individual conventional approaches address specific cases of use and requirements. In particular, approaches that combine competing safety objectives of supplying an energy vehicle electrical system consumer and at the same time isolating faults of the consumer from the energy vehicle electrical system are currently not on the market. Furthermore, conventional complex approaches use d.c. voltage converters, for example.

In many cases, only fusible cutouts are used, which protect the line circuit against overheating by disconnecting the faulty current path after the melting integral of the cutout has been exceeded. For use in high-availability vehicle electrical systems, however, fusible cutouts are usable only to a very limited extent: On the one hand, spontaneous failures may occur, which interrupt the availability of an energy supply to connected consumers. On the other hand, fusible cutouts require a relatively high melting integral for disconnection, which gives rise to high short-circuit currents in the millisecond range. These high short-circuit currents may cause critical voltage drops in the vehicle electrical system, which interrupt the supply of other critical consumers.

In addition, the triggering behavior of fusible cutouts is not deterministic, particularly in cases of moderate overloads. In the case of 1.5 times the nominal current, for example, a common automotive cutout may trigger already after 90 seconds or only after one hour.

### SUMMARY

In accordance with the present invention, a method for configuring a vehicle electrical system, and a vehicle electrical system are provided. Specific embodiments of the present invention result from the disclosure herein.

In accordance with an example embodiment of the present invention, a method for configuring a vehicle electrical system of a motor vehicle is provided, at least one consumer being provided in the vehicle electrical system. Within the scope of the configuration of a vehicle electrical system, at least one of the at least one consumers is assigned an electrical module, which in turn is selected from a group of modules, a first consumer criterion, which refers to a supply requirement of the at least one consumer, and a second consumer criterion, which refers to a degree of feedback of the at least one consumer, being taken into consideration when selecting the electrical module.

In a refinement of the present invention, all consumers to be provided in the vehicle electrical system are assigned an appropriate electrical or electronic module. It is also possible, however, to assign suitable electrical modules only to some selected consumers. This assignment provides initially for the selection of the suitable module(s) and subsequently for taking this module or these modules into consideration in the circuit design of the vehicle electrical system.

The electrical modules of the module group are typically categorized according to a first module criterion, which refers to a reliability of supply, and according to a second module criterion, which refers to a disconnectability. When selecting the electrical module for the at least one consumer, the first consumer criterion and the second consumer criterion are then compared with the first module criteria and the second module criteria of the electrical modules in the module group. On the basis of the first consumer criterion and the second consumer criterion, the electrical module is thus selected whose two module criteria match the two consumer criteria. This means for example that a consumer that has high requirements regarding supply, but only a low degree of feedback, is assigned an electrical module that offers a high degree of supply reliability, but only a low disconnectability. In addition to the aforementioned criteria, it is of course possible to take into consideration further criteria, such as cost and availability for example, when making the selection.

The example method according to the present invention thus provides for a configuration of a vehicle electrical system or energy vehicle electrical system, to be performed in particular also in automated fashion, within the scope of which at least one electrical or electronic module is selected from a module group, which in turn is assigned to a consumer. The type of consumer is taken into consideration in the selection, criteria being used in this consideration. In the process, the consumer criterion of the supply requirement is juxtaposed to the module criterion of the supply reliability, and the consumer criterion of the degree of feedback is juxtaposed to the module criterion of the disconnectability.

The configuration of the vehicle electrical system is thus understood herein as the selection of suitable electrical modules that are used to connect or couple consumers to the vehicle electrical system. Said consumers are then part of the vehicle electrical system. In the selection, it is possible to access a library of consumers, which is herein referred to as a module group. Possible electrical modules are established in this module group, it being possible for these to be subdivided or categorized according to criteria of supply reliability and disconnectability. This means that each electrical module in the module group is assigned a first parameter or a first value for the supply reliability and a second parameter or a second value for the disconnectability. These two parameters or values, which comprise a numerical value only in a refinement, provide information about the electrical module with respect to the two aforementioned criteria. The quality of the electrical module with respect to the supply reliability and the quality with respect to the disconnectability is thus indicated.

The consumers that are to be coupled to the vehicle electrical system are classified accordingly. The consumer criterion of the supply requirement provides information as to how significant a reliable operation of the consumer is for the vehicle or for the driver of the vehicle. Thus, safety-related consumers, such as steering and brake for example, normally require a higher degree of supply reliability than consumers that are not safety-related, such as comfort consumers such as an air conditioning system for example. The consumer criterion of the degree of feedback provides information about possible effects of a defective consumer on the rest of the vehicle electrical system. This defines how significant it is whether, in particular also within what time frame, the defective consumer can be disconnected from the rest of the vehicle electrical system.

Module concepts are thus provided that may be used in energy motor vehicle electrical systems for distributing energy to the consumers. This addresses both the requirements regarding the availability of an energy supply for consumer channels as well as the requirements regarding the reliable disconnectability of consumer channels if these imperil the integrity of the input-side energy supply through short circuits.

The vehicle electrical system in accordance with an example embodiment of the present invention is designed for use in a motor vehicle, comprising at least one consumer, at least one of the at least one consumer being assigned an electronic module, which is selected according to the method described above.

The electrical module may be selected from a group of modules, which comprises a first electrical module, which has a switch and a cutout, which are connected in parallel to each other, a second electrical module, which has a cutout with a simple plausibility check, a third electrical module, which has a cutout with redundant current measurement and/or a fourth electrical module, which has two switches connected in parallel.

For the switches, it is possible to use electronic switches for example, such as transistors, in particular field-effect transistors such as MOSFETs, for example. For the cutouts, it is possible to use fusible cutouts and other suitable cutouts.

Additional advantages and further developments of the present invention derive from the specification and the appended figures.

It is understood that the aforementioned features and the features yet to be described below may be used not only in the respectively indicated combination, but also in other combinations or in isolation, without departing from the scope of the present invention.

### BRIEF DESCRIPTION OF THE DRAWINGS

FIG. 1 shows a first specific embodiment of a vehicle electrical system, in accordance with the present invention.

FIG. 2 shows a second specific embodiment of a vehicle electrical system, in accordance with the present invention.

FIG. 3 shows a third specific embodiment of a vehicle electrical system, in accordance with the present invention.

FIG. 4 shows a fourth specific embodiment of a vehicle electrical system, in accordance with the present invention.

FIG. 5 shows a fifth specific embodiment of a vehicle electrical system, in accordance with the present invention.

### DETAILED DESCRIPTION OF EXAMPLE EMBODIMENTS

The present invention is represented schematically in the figures on the basis of specific example embodiments and described in detail below with reference to the figures.

Some possible specific embodiments are indicated in the following. It should be noted that different realization modules are derived for different requirement areas, which respectively divide via the requirement into the guaranteed ability to isolate consumer feedbacks, the degree of feedback or the freedom from feedback, and the guaranteed ability to provide a interruption-free connection to the energy supply, the supply reliability.

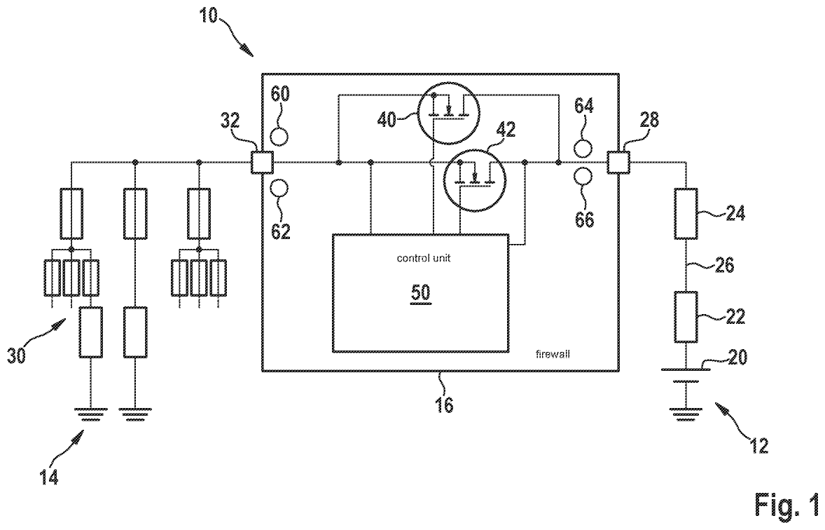

FIG. 1 shows a first specific embodiment of the presented vehicle electrical system, which is denoted as a whole by reference numeral 10. In this specific embodiment, a disconnection occurs in accordance with ASIL C and a supply in accordance with QM. In vehicle electrical system 10, the figure shows a first vehicle electrical system channel 12 and a second vehicle electrical system channel 12, which are connected to each other via a firewall 16.

A battery 20 is provided in first vehicle electrical system channel 12 for the energy supply. The figure additionally shows an internal resistance Rᵢ 22 of battery 20 and a line resistance R_{cu} 24 of line 26. This vehicle electrical system channel 12, which is connected to terminal 28, thus serves to supply energy, and a reliable operation of this first vehicle electrical system channel 12 should be ensured.

In second vehicle electrical system channel 14, QM consumers 30 are provided, i.e., comfort consumers such as ventilators for example, which are not safety-related. These thus have low requirements in terms of supply requirements. In case of a fault, however, these may have a negative effect on the entire vehicle electrical system 10, which means a low degree of feedback freedom and a high degree of feedback such that it should be ensured that these can be reliably disconnected from vehicle electrical system 10. The second vehicle electrical system channel, which is connected to terminal 32, and its consumers thus do not have a high rating with respect to the supply requirement.

A first switch 40, in this case a MOSFET, and a second switch 42, in this case a MOSFET, are provided in firewall 16. Furthermore, a control unit 50 is provided, in which a current measuring device, an overcurrent switch-off device, drivers for the MOSFETs, a MOSFET diagnostic device, possibly a processing unit and its supply and monitoring devices are provided. This control unit may be a combination of discrete logic and processing unit and may possibly also contain one or multiple application-specific integrated circuits in order to bundle functionalities. Furthermore, a first sensor 60 for voltage measurement, a second sensor 62 for temperature measurement, a third sensor 64 for voltage measurement and a fourth sensor 66 for current measurement are provided.

The present specific embodiment shows: If two parallel current paths are used, then each of these may be controlled individually. During the run time, the hardware protection threshold value for each path or vehicle electrical system channel is periodically reduced in order to trigger the diagnosis. As soon as the hardware threshold value was triggered at the correct level, the voltage drop of the complete current path will change due to a growing resistance of the entire switch. With this concept, the entire safety-related loop including current measuring device, comparator, switch-off logic, gate driver and MOSFET channel is tested. The objective is to fulfill the ASIL metrics at a high diagnostic coverage of the MOSFETs and of the control/diagnostic circuit or the ASIC.

The option described above for disconnecting two vehicle electrical system channels 12, 14 may be considered in combination with the electrical modules explained below or separately, i.e., independently of the coupling of the consumers to the electrical modules.

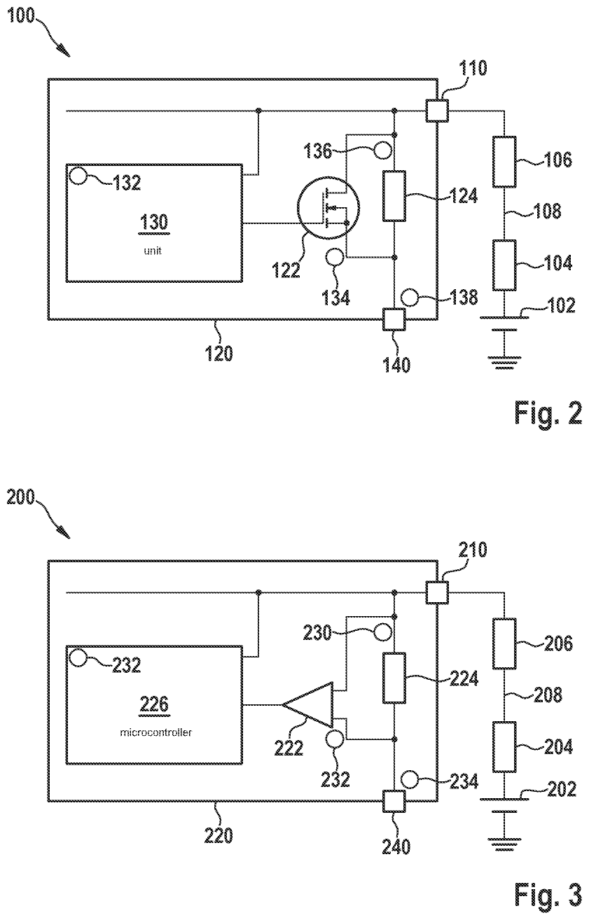

FIG. 2 shows a further specific embodiment of the described vehicle electrical system, which is denoted as a whole by reference numeral 100. In this specific embodiment, a disconnection occurs in accordance with QM and a supply in accordance with ASIL C. In vehicle electrical system 100, the figure shows a battery 102 as energy supply, an internal resistance Rᵢ 104 of battery 102 and a line resistance R_{cu} 106 of line 108. This supply branch is connected to terminal 110.

A first electrical module 120 is connected to terminal 110, in which a switch 122, in this case a MOSFET, and a cutout 124, in particular a fusible cutout, are connected in parallel to each other. Furthermore, a unit 130, a first sensor 132 for temperature measurement, a second sensor 134 for current measurement, a third sensor 136 for temperature measurement and a fourth sensor 138 for voltage measurement are provided. In an additional specific embodiment, current sensor 134 may also be implemented in duplicate for reasons of redundancy, e.g., in the form of a first measurement via the voltage drop on the parallel circuit made up of the cutout and the MOSFET and in a second case via an additional, independent measurement method such as, for example a series-connected shunt resistance or a Hall element.

By measuring the output voltage it is possible to detect fault patterns such as a faulty opening or drift of cutout and MOSFET. Via the combination of temperature sensor and current sensor, it is possible, on the one hand, to calculate the temperature variation of the cutout/MOSFET for the current measurement. On the other hand, a drift of the resistances of the MOSFET or cutout may be inferred from the combination of increased temperature sensor values and implausible measurement values of the current sensor(s).

The already described brief opening of the semiconductor switch also makes it possible to bring about deliberately a change of the resistance value from the parallel connection of the cutout and the MOSFET. As a diagnostic measure, a check may be performed to determine whether this change results in a change of the sensor value(s), in particular of the voltage drop across the parallel connection of the MOSFET and the cutout.

A consumer, which is assigned to the first electronic module 120, may be connected to a terminal 140.

The presented embodiment thus provides for a reliable supply of loads with high currents, which at the same time by themselves prevent a negative feedback on the vehicle electrical system, which allows for the use of a fusible cutout.

In this embodiment, a MOSFET and a fusible cutout are arranged in parallel. In normal operation, the MOSFET is usually in a conductive state and two parallel or redundant paths carry the current load together. A brief, i.e., shorter than the fault tolerance time, opening of the MOSFET for diagnostic purposes makes it possible to monitor the cutout resistance. This is done in order to check for latent faults in the cutout, that is, open or drift, and in the MOSFET, i.e., that the latter is not able to open.

If cutout 124 shows an incorrect increased resistance, the MOSFET path is designed to carry the entire current.

In the event of a fault of the MOSFET or ASIC, cutout 124 is designed to conduct the entire current in order to supply the consumer or the load. The risk of systematic faults within the MOSFET or its driver, for maintaining the MOSFET in a conductive state, may be avoided by the parallel cutout 124, it being possible to exclude systematic faults in the parallel cutout path by a suitable design.

Due to the current distribution between the MOSFET and cutout 124, it is possible to keep aging-related currents away from the cutout and the MOSFET. It is therefore possible to keep aging-related faults away from both the MOSFET and the cutout.

If this path is used for higher currents, cutout 124 is not able to ensure the quick disconnection from the load, and therefore the load must ensure that a negative influence is avoided, i.e., the load must have a high degree of freedom from feedback.

Due to the reduced aging of the cutout and of the MOSFET, it is possible to use cutouts that have a lower tolerance without a diffusion zone, which is normally used in order to increase the melting integral I²t. The design without the diffusion zone makes the triggering behavior of the cutouts more predictable. In addition, the cutout becomes less sensitive to thermal stress.

In the event of short circuits at the channel output, it is possible to keep the parallel MOSFET channel closed for a delay time, which is controlled by the microcontroller. This then produces the same behavior as a delayed-action fuse, but without the disadvantage of the extremely increased tolerance.

FIG. 3 shows a third specific embodiment of the vehicle electrical system, which is denoted as a whole by reference numeral 200. In this specific embodiment, a disconnection occurs in accordance with QM and a supply in accordance with ASIL A. In vehicle electrical system 200, the figure shows a battery 202 as energy supply, an internal resistance Rᵢ 204 of battery 202 and a line resistance R_{cu} 206 of line 208. This supply branch is connected to terminal 210.

A second electrical module 220 is connected to terminal 210, which comprises a differential amplifier 222, a fusible cutout 224 and a microcontroller 226. Furthermore, a first sensor 230 for temperature measurement, a second sensor 232 for current measurement and a third sensor 234 for voltage measurement are provided.

Temperature sensor 230 makes it possible to measure a temperature rise at cutout 224 in order to use this to calculate a temperature compensation of the cutout resistance. It is furthermore possible to detect an excessive temperature increase as a result of a fault (drift) of cutout 224. The knowledge of the temperature-compensated internal resistance of the cutout and of the voltage drop at cutout 224 across the difference amplifier 222 makes it possible to calculate, on the one hand, the current flow through cutout 224 and, on the other hand, to record the aging-related stress on cutout 224 and, if necessary, to provide an aging model.

A consumer may be connected to a terminal 240, which is then connected to vehicle electrical system 200 via second electrical module 220.

The embodiment shown provides for a safety supply through cutout 224. This configuration prevents a negative feedback of loads and comprises a cutout with a simple plausibility check.

Via the diagnosed cutout 224, it is possible to achieve, for example, a supply reliability in accordance with ASIL A. If this is sufficient, this may be accomplished by rainflow counting of the current pulses and by providing stress analyses and aging prediction. The vehicle electrical energy system supply channel and the circuit wiring to the load produce a voltage divider between the source and the short circuit.

The energy vehicle electrical system configuration must ensure that a short circuit at the load does not impair the reliable supply of other loads.

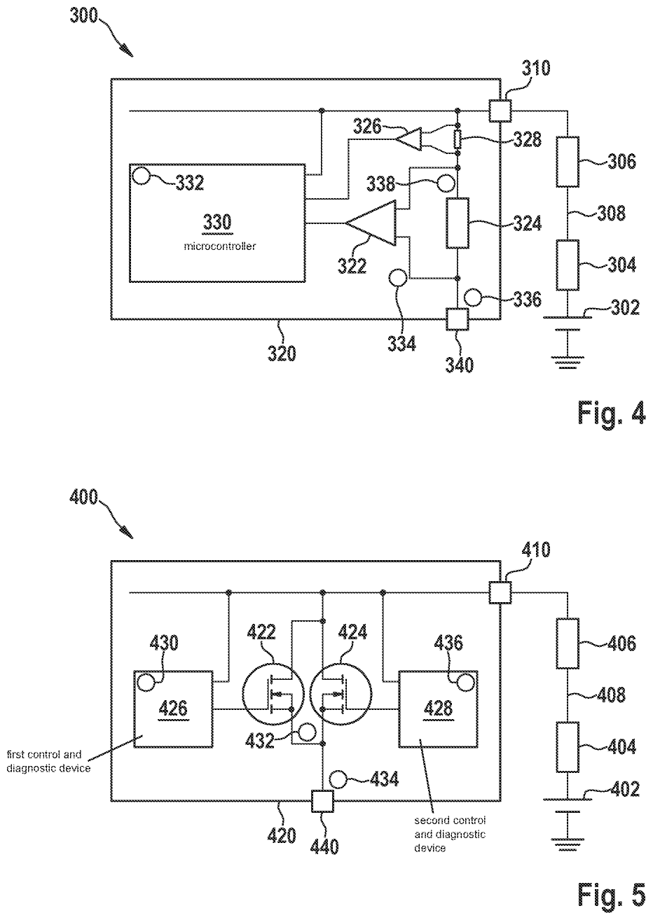

FIG. 4 shows a fourth specific embodiment of the vehicle electrical system, which is denoted as a whole by reference numeral 300. In this specific embodiment, a disconnection occurs in accordance with QM and a supply in accordance with ASIL A(C) or B(D). In vehicle electrical system 300, the figure shows a battery 302 as energy supply, an internal resistance Rᵢ 304 of battery 302 and a line resistance R_{cu} 306 of line 308. This supply branch is connected to terminal 310.

A third electrical module 320 is connected to terminal 310, which comprises a first differential amplifier 322, a fusible cutout 324, a second differential amplifier 326 having an associated measuring resistor 328, and a microcontroller 330. Furthermore, a first sensor 332 for temperature measurement, a second sensor 334 for current measurement, a third sensor 336 for voltage measurement and a fourth sensor 338 for temperature measurement are provided.

In this specific embodiment as well, it is possible to detect serious faults via the measurement of the output voltage with the aid of third sensor 336. For a detailed evaluation of the functional state of cutout 324, it is possible to determine the expected internal resistance of cutout 324 as a function of the temperature, which is measured by fourth sensor 338.

It is possible to obtain current information via the knowledge of the voltage drop at cutout 324, via the differential amplifier 322, and of the temperature-compensated resistance. This current information may be compared with the current information from second differential amplifier 326 via measuring resistor 328 in order to allow for a mutual plausibility check of the two items of current information and in order to detect a resistance drift of cutout 324.

A consumer may be connected to a terminal 340, which is then connected to vehicle electrical system 300 via second electrical module 320.

This embodiment provides for a safety supply through cutout 324. The energy vehicle electrical system configuration prevents a negative feedback of loads.

Cutout 324 must ensure an availability in order to ensure an ASIL A(C) standard in the case of a manual driving operation or, for example, an ASIL B(D) standard in an automated driving operation by an improved diagnosis. It is therefore advantageous to monitor the cutout resistance and its behavior by an additional measuring resistor measurement of the current.

The energy vehicle electrical system supply channel and the circuit wiring to the load produce a voltage divider between the source and the short circuit.

The energy vehicle electrical system configuration must ensure that a short circuit on the load does not impair the reliable supply of other loads.

FIG. 5 shows a fifth specific embodiment of the described vehicle electrical system, which is denoted as a whole by reference numeral 400. In this specific embodiment, a disconnection occurs in accordance with ASIL B(D) and a supply in accordance with ASIL B(D). In vehicle electrical system 400, the figure shows a battery 402 as energy supply, an internal resistance Rᵢ 404 of battery 402 and a line resistance R_{cu} 406 of line 408. This supply branch is connected to terminal 410.

A fourth electrical module 420 is connected to terminal 410. This fourth electrical module 420 provides a first switch 422, in this case a MOSFET, a second switch 424, in this case a MOSFET, a first control and diagnostic device 426 and a second control and diagnostic device 428. Furthermore, a first sensor 430 for temperature measurement, a second sensor 432 for current measurement, a third sensor 434 for voltage measurement and a fourth sensor 436 for temperature measurement are provided.

Analogous to the previous explanations, it is possible to use the voltage measurement for detecting serious faults. Since in this embodiment an output 440 may be switched off entirely via semiconductors, it is possible to check the disconnectability of both switches 422 and 424 by opening both switches, while the vehicle is in a safe state. In this concept, the current measurement by second sensor 432 occurs via the determination of the voltage drop across both switches 422 and 424. By installing an additional resistance-based current measuring device in series, it is possible to improve the quality of the measurement further. Each switch 422, 424 is assigned a temperature sensor, via which it is possible, on the one hand to calculate a temperature compensation of the switch resistor and, on the other hand, to infer faults in the thermal connection of the MOSFETs from the temperature increase with respect to the surroundings.

In order to protect against semiconductor damage in the event of short circuits, an autonomous quick-reacting overload switch is integrated in modules 426 and 428. These respectively compare the instantaneously flowing current flow from the sensor system 432 installed in the module with a variable limit value. A diagnosis of the protective device with respect to latent faults is possible by trimming the switch-off limit to values below the instantaneously applied current. As a reaction, the autonomous overload switch should detect the overload and switch off the respective switch 422 or 424. This may be verified by remeasuring the voltage drop across switches 422 and 424, respectively. This diagnosis may be performed after or also during running operation provided that one of the two independent current paths always remains closed.

A consumer may be connected to terminal 440, which is then connected to vehicle electrical system 400 via second electrical module 420.

The embodiment thus shows a reliable supply merely by way of MOSFETs. For this purpose, two parallel MOSFET channels guarantee the availability of the voltage supply according to the ASIL B (D) standard, which may be distributed to two A (D) for each channel. Furthermore, a quick disconnection is made possible.

What is claimed is:

1. A method for configuring a vehicle electrical system of a motor vehicle, at least one consumer being provided in the vehicle electrical system, the method comprising the following steps:
within a scope of the configuration of the vehicle electrical system, assigning at least one of the at least one consumer an electrical module, the electrical module being selected from a group of electrical modules;
wherein, a first consumer criterion, which refers to a supply requirement of the at least one consumer, and a second consumer criterion, which refers to a degree of feedback of the at least one consumer, are taken into consideration in the selection of the electrical module.

2. The method as recited in claim 1, wherein the electrical modules in the group of electrical modules are categorized according to a first module criterion, which refers to a supply reliability, and according to a second module criterion, which refers to a disconnectability, and wherein, in the selection of the electrical module for the at least one consumer, the first consumer criterion and the second consumer criterion are compared with the first module criteria of the electrical modules and the second module criteria of the electrical modules in the group of electrical modules.

3. The method as recited in claim 1, wherein the group of electrical modules includes a first electrical module, which has a switch and a cutout, which are connected in parallel to each other.

4. The method as recited in claim 1, wherein the group of electrical modules includes a second electrical module, which has a cutout with a simple plausibility check.

5. The method as recited in claim 1, wherein the group of electrical modules includes a third electrical module, which has a cutout with redundant current measurement.

6. The method as recited in claim 3, wherein the cutout is a fusible cutout, or a conductor track fuse, or a narrowed current track.

7. The method as recited in claim 1, wherein the group of electrical modules includes a fourth electrical module, which has two switches connected in parallel.

8. The method as recited in claim 1, wherein a firewall is provided to connect vehicle electrical system channels to one another.

9. A vehicle electrical system for a motor vehicle, comprising:
at least one consumer which is connected to the vehicle electrical system via an electrical module, the electrical module being selected from a group of electrical modules;
wherein, a first consumer criterion, which refers to a supply requirement of the at least one consumer, and a second consumer criterion, which refers to a degree of feedback of the at least one consumer, are taken into consideration in the selection of the electrical module.

10. The vehicle electrical system as recited in claim 9, wherein the electrical module is selected from a group of electrical modules, the group of electrical modules including: (i) a first electrical module, which has a switch and a cutout, which are connected in parallel to each other, and/or (ii) a second electrical module, which has a cutout with a simple plausibility check, and/or (iii) a third electrical module, which has a cutout with redundant current measurement, and/or (iv) a fourth electrical module, which has two switches connected in parallel.

11. The vehicle electrical system as recited in claim 9, wherein the vehicle electrical system includes at least two vehicle electrical system channels, which are connected to one another via a firewall.
